(19) United States
(12) Patent Application Publication
(10) Pub. No.: US 2026/0136805 A1
(43) Pub. Date: May 14, 2026

(54) DISPLAY PANEL AND DISPLAY MODULE

(71) Applicants: Hefei Visionox Technology Co., Ltd., Hefei (CN); Visionox Technology Inc., Kunshan (CN)

(72) Inventors: Zhao ZU, Hefei (CN); Qing BAI, Hefei (CN); Peng QIN, Kunshan (CN)

(73) Assignees: Hefei Visionox Technology Co., Ltd., Hefei (CN); Visionox Technology Inc., Kunshan (CN)

(21) Appl. No.: 19/386,137

(22) Filed: Nov. 11, 2025

(30) Foreign Application Priority Data
Nov. 12, 2024 (CN) 202411614701.4

(51) Int. Cl. H10K 59/80; H10K 59/12; H10K 59/122; H10K 102/00

(52) U.S. Cl. CPC H10K 59/80522; H10K 59/1201; H10K 59/122; H10K 59/80521; H10K 2102/351

(57) ABSTRACT

The present disclosure provides a display panel and a display module. The display panel includes a substrate, a light-emitting unit, a first electrode, and an isolation structure. The isolation structure is disposed on one side of the substrate and encloses a plurality of isolation openings. At least part of the light-emitting unit is located within the isolation opening. The first electrode covers the light-emitting unit and includes a thinned portion. At least part of the thinned portion is electrically connected to the isolation structure, and a thickness of the thinned portion is less than a thickness of other regions of the second electrode. By controlling the morphology of the first electrode, a lap resistance can be reduced while achieving an effective lap with the isolation structure, thereby reducing subsequent display abnormalities.

### CROSS-REFERENCE TO RELATED APPLICATIONS

The present application claims priority to the Chinese Patent Application No. 202411614701.4, titled “DISPLAY PANEL AND DISPLAY MODULE”, filed on Nov. 12, 2024, and the entire contents of the aforementioned application are hereby incorporated by reference in its entirety.

### FIELD

The present disclosure relates to the field of display technologies, and in particular to a display panel and a display module.

### BACKGROUND

An organic light-emitting diode (OLED) is an organic thin-film electroluminescent unit, which has received great attention and has been widely used in electronic display products thanks to its advantages such as simple preparation process, low cost, low power consumption, high luminance, wide angle of view, high contrast, and enabling flexible display.

However, current electronic display products are prone to display abnormalities due to limitations of their own structural design.

### SUMMARY

In view of this, embodiments of the present disclosure are to provide a display panel and a display module. The display panel can reduce display abnormalities.

One embodiment of the present disclosure discloses a display panel. The display panel includes:
a substrate, a first electrode, a light-emitting unit and an isolation structure, where an isolation structure layer is disposed on the substrate and includes a plurality of isolation structures that enclose a plurality of isolation openings,
at least part of the light-emitting unit is located within the isolation opening, and the first electrode covers the light-emitting unit and comprises a thinned portion and a body portion, the body portion covering a central region of the isolation opening and extending outwardly to form the thinned portion, at least part of the thinned portion being electrically connected to the isolation structure, and a thickness of the thinned portion being less than a thickness of the body portion.

In one of the implementations, the first electrode includes the thinned portion and the body portion, where an edge of the thinned portion is lapped with the isolation structure, and the thinned portion becomes thinner as it is closer to the isolation structure.

In one embodiment, the thinned portion includes a lap area and a transition area, the lap area being electrically connected to the isolation structure.

In one of the implementations, edges on opposite sides of the first electrode each include the thinned portion, the thinned portion being electrically connected to the corresponding isolation structure.

In one embodiment, the thinned portion of each of the edges on the opposite sides of the first electrode includes a lap area and a transition area, the lap area being electrically connected to the corresponding isolation structure.

In one embodiment, the transition area is located between the body portion and the lap area and includes a first transition area and a second transition area, the first transition area being close to the lap area, the second transition area being close to the body portion, and the lap area being electrically connected to the isolation structure.

In one of the implementations, the isolation structure includes a support portion, a base portion, and a roof portion, one side of the support portion being disposed on the base portion, the base portion being disposed on the substrate, the roof portion being disposed on one side of the support portion away from the substrate, the roof portion having an end on either side, and a thickness of a region corresponding to an orthographic projection of the end on the first electrode is less than or equal to 70% of the thickness of the body portion of the first electrode.

In one embodiment, the support portion is made of aluminum, the base portion is made of molybdenum or titanium nitride, and the roof portion is made of titanium.

In one of the implementations, the orthographic projection of the end on the first electrode is in the transition area, and a ratio of a thickness of the transition area to the thickness of the body portion is less than or equal to 0.7.

In one embodiment, the ratio of the thickness of the transition area to the thickness of a film layer of the body portion is in a range of 0.3 to 0.7.

In one embodiment, the orthographic projection of the end on the first electrode is in a first transition area of the first electrode, and a ratio of a thickness of the first transition area to the thickness of the body portion is less than or equal to 0.7.

In one embodiment, the orthographic projection of the end on the first electrode coincides with the first transition area of the first electrode, and the ratio of the thickness of the first transition area to the thickness of the body portion is in a range of 0.3 to 0.7.

In one of the implementations, a thickness ratio of the body portion to the base portion is less than 2.

In one embodiment, the thickness ratio of the body portion to the base portion is less than or equal to 1.5.

In one embodiment, the thickness ratio of the body portion to the base portion is in a range of 1.01 to 1.4.

In one of the implementations, the first electrode is lapped with a side surface of part of the support portion and the base portion, or is lapped with the base portion.

In one embodiment, the thinned portion is lapped with the side surface of part of the support portion and the base portion, or is lapped with the base portion.

In one of the implementations, a pixel defining layer disposed on the substrate is further included, where the isolation structure is disposed on one side of the pixel defining layer away from the substrate.

In one of the implementations, the display panel further includes a planarization layer disposed on one side of the substrate, where the pixel defining layer is disposed on one side of the planarization layer away from the substrate, and the one side of the planarization layer away from the substrate has a second electrode disposed thereon.

In one embodiment, the planarization layer covers an active area or covers the active area and a non-active area outside the active area.

In one of the implementations, the pixel defining layer is provided with a pixel opening, an orthographic projection of the body portion on the substrate covers an orthographic projection of the pixel opening and part of the pixel defining layer surrounding the pixel opening on the substrate, and the pixel opening corresponds in position to the isolation opening and has an inclined surface.

In one embodiment, an included angle α between the inclined surface and a plane in which the substrate is located is between 30° and 75°.

Based on the same concept, the present application provides a display module, including a display panel as described above.

Compared with the prior art, the present disclosure provides a first electrode (cathode) with an optimized structure. A thinned portion is provided on a side of the first electrode that is lapped with the isolation structure, at least part of the thinned portion is electrically connected to the isolation structure, and the thickness of the thinned portion is less than a thickness of other regions of the first electrode. This reduces a lap resistance while achieving an effective lap with the isolation structure, thereby avoiding potential display abnormalities.

### BRIEF DESCRIPTION OF THE DRAWINGS

In order to more clearly describe the embodiments of the present disclosure or in the related art, the accompanying drawings for describing the embodiments or the related art will be briefly described below. The accompanying drawings in the description below show merely the embodiments of the present disclosure.

FIG. 1 is a schematic diagram of a display panel according to an embodiment of the present disclosure;

FIG. 2 is a schematic sectional view at A in FIG. 1;

FIG. 2a is a schematic enlarged view of the left side of the dash-dotted line in FIG. 2;

FIG. 3 is a schematic diagram depicting an electrode covering an insulating layer according to an embodiment of the present disclosure;

FIG. 4 is a schematic diagram of an electrode preparation system according to an embodiment of the present disclosure; and

FIG. 5 is a schematic flowchart of an electrode preparation method according to an embodiment of the present disclosure.

### DETAILED DESCRIPTION OF THE EMBODIMENTS

In order to make the embodiment of the present disclosure clearer, the present disclosure is further described below in detail with reference to some embodiments and the accompanying drawings.

It should be noted that unless otherwise defined, the technical or scientific terms used in the embodiments of the present disclosure shall have general meanings as understood by those of ordinary skill in the art to which the present disclosure pertains. “First”, “second”, and like words used in the embodiments of the present disclosure do not indicate any order, quantity, or importance, but are merely used to distinguish between different components. “Include” or “comprise” or like words mean that an element or item preceding the term encompasses an element or item or its equivalent listed after the term, without excluding other elements or items. “Connect” or “connected” or like words are not limited to a physical or mechanical connection, but may include an electrical connection, whether direct or indirect. “Up”, “down”, “left”, “right”, and the like are merely used to indicate a relative positional relationship, and the relative positional relationship may change accordingly when an absolute position of the described object changes.

A process for fabricating an OLED (Organic Light-Emitting Diode) display product is roughly divided into an array substrate stage, a light-emitting layer preparation stage, and a module stage.

In the light-emitting layer preparation stage, a light-emitting unit is formed by evaporation on the entire surface of an array substrate on which an isolation structure is formed. Then, a cathode layer and an encapsulation layer are deposited by evaporation on the light-emitting unit. A light-emitting layer (sub-pixel) is fabricated on the array substrate by means of etching. The sub-pixel can be energized and then turned on to be properly lit up only when the cathode is properly lapped with the isolation structure (also referred to as an auxiliary cathode).

The applicant has conducted further research on the cathode and found that, the morphology of the cathode has a significant impact on whether the cathode is properly lapped with the auxiliary cathode. In a case of an abnormal cathode lap, a resistance value at a lap position is higher than a preset value, and there is a risk of display abnormalities of a corresponding sub-pixel in subsequent use.

In view of this, the applicant proposes a display panel and a display module. The display panel includes a substrate, a light-emitting unit, a first electrode, and an isolation structure. The isolation structure is disposed on one side of the substrate and encloses a plurality of isolation openings. At least part of the light-emitting unit is located within the isolation opening. The first electrode covers the light-emitting unit and includes a thinned portion. At least part of the thinned portion is electrically connected to the isolation structure, and a thickness of the thinned portion is less than a thickness of other regions of the first electrode. The morphology of the first electrode is designed in such a way that it has the thinned portion and can be reliably lapped with the isolation structure/auxiliary cathode, thereby reducing display abnormalities caused by a poor lap.

An electrode preparation method, a display panel, and a display module provided by the present application will be described below with reference to the accompanying drawings.

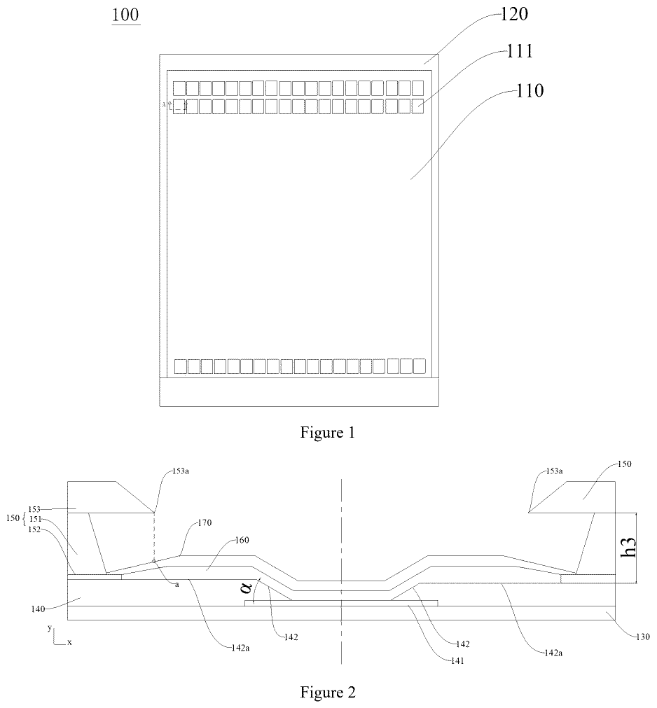

FIG. 1 is a schematic diagram of a display panel according to an embodiment of the present application.

The display panel 100 includes a light-emitting area 110 and a non-light-emitting area 120 (also referred to as a bezel area) outside the light-emitting area 110.

The light-emitting area 110 includes regularly arranged light-emitting devices 111, each light-emitting device 111 including a plurality of sub-pixels, such as red sub-pixels, green sub-pixels, and blue sub-pixels (not shown), or red sub-pixels, green sub-pixels, blue sub-pixels, and white sub-pixels.

In one embodiment, the sub-pixels in the light-emitting area are obtained by full-surface evaporation together with etching. The preparation process does not require a mask. For example, the red sub-pixels are prepared by performing full-surface evaporation and etching on the array substrate, and the green sub-pixels are prepared by performing full-surface evaporation and etching on the array substrate, and a high-PPI (Pixels Per Inch, also called a unit of pixel density) display panel can be obtained. For example, the sub-pixels are prepared by performing full-surface evaporation and etching on the array substrate. No limitations are imposed on a sequence of preparing the red/green/blue sub-pixels.

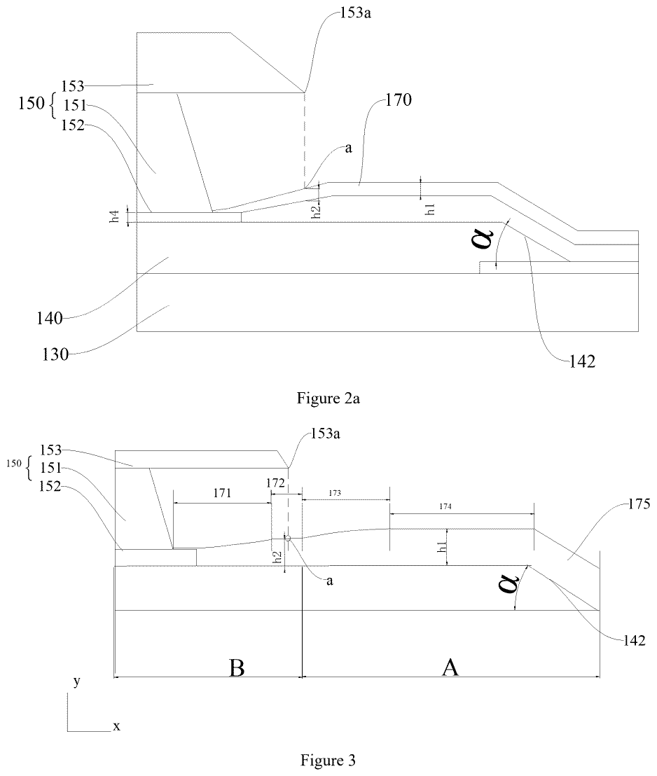

Next, referring to FIG. 2, the structure of a pixel will be described by taking one pixel as an example. FIG. 2 is a schematic view of a section at A in FIG. 1, with an encapsulation layer omitted.

The display panel includes a substrate 130, an insulating layer 140, a second electrode 141, a light-emitting unit 160, a first electrode 170, and an isolation functional layer.

The substrate 130 is a flexible substrate, which may be made of a material selected from polyimide (PI), polyethylene naphthalate (PEN), polyethylene terephthalate (PET), etc., or a mixed material of a plurality of the above-mentioned materials. In one embodiment, the substrate 130 may be a rigid substrate, which may be made of a material selected from glass. In one embodiment, a drive circuit for driving a pixel is provided on one side of the substrate. A topology of the drive circuit may be a 7T1C circuit, a 7T2C circuit, an 8T1C circuit, an 8T2C circuit, etc., and is not limited herein, as long as it can drive a pixel. The substrate may be made of a material selected from polyimide (PI), polyethylene naphthalate (PEN), polyethylene terephthalate (PET), etc., or a mixed material of a plurality of the above-mentioned materials. In one embodiment, the substrate may be made of a material such as glass.

The second electrode 141 is disposed on the substrate 130. In the same light-emitting device, second electrodes 141 for a plurality of sub-pixels may be connected to each other, and cathodes/second electrodes are physically isolated from each other to realize independent control of the sub-pixels. That is, cathodes of different sub-pixels are not electrically connected directly or indirectly. In one embodiment, a cathode corresponding to the sub-pixel may be connected to an external circuit through a separate wiring, or through an auxiliary electrode.

The insulating layer 140 (the insulating layer is also referred to as a pixel defining layer) is disposed on the substrate 130 and defines a pixel opening. The pixel defining layer is configured to cover a gap between adjacent second electrodes 141. The pixel opening exposes at least part of the second electrode 141 for an electrical connection to the light-emitting unit 160 thereon. The pixel defining layer may be prepared through a patterning process. In a light-emitting region, the pixel defining layer is used to define a pixel opening of a pixel. A shape of the pixel opening matches a shape of the pixel, such as square, diamond, circular, elliptical, etc., which is not limited herein.

In one embodiment, a planarization layer is disposed on one side of the substrate 130, and the pixel defining layer is disposed on one side of the planarization layer away from the substrate 130. The one side of the planarization layer away from the substrate 130 has the second electrode 141 disposed thereon, and the planarization layer covers an active area. In one embodiment, the planarization layer covers the active area and a non-active area. In other implementations, the second electrode 141 is embedded in the one side of the planarization layer away from the substrate 130, with a top surface of the second electrode exposed for an electrical connection to the light-emitting unit 160 thereon.

The isolation functional layer includes a plurality of isolation structures 150 that enclose a plurality of isolation openings 154. The isolation structure 150 includes a support portion 151, a base portion 152, and a roof portion 153 (roof). One side of the support portion 151 is disposed on the base portion 152, the base portion 152 is disposed on the pixel defining layer 140, and the roof portion 153 is disposed on one side of the support portion 151 away from the pixel defining layer 140. The roof portion 153 has an end 153a (an edge point of the roof) on either side. A thickness h2 of a film layer (transition area) of a region of the first electrode/cathode corresponding to an orthographic projection of the end 153a of the roof portion 153 on the substrate is 70% or less of a thickness h1 of a film layer of a body portion (e.g., a body flat area). In one embodiment, the support portion 151 is made of aluminum. The base portion 152 is made of molybdenum or titanium nitride. The roof portion 153 is made of titanium. The composition, preparation, and other contents of the isolation structure (or referred to as a barrier structure or an isolation column) are further described in patents Nos. CN118251982A, 202410864269.8, PCT/CN2024/098407, PCT/CN2024/102783, PCT/CN2024/098217, PCT/CN2024/099419, and PCT/CN2024/099072, which are incorporated herein by reference.

At least part of the light-emitting unit 160 is located within the isolation opening, one side of the light-emitting unit close to the substrate is electrically connected to the second electrode 141 (anode), and one side of the light-emitting unit away from the second electrode 141 (anode) is covered by the first electrode.

The first electrode covers the light-emitting unit 160, and at least part of the first electrode is lapped with the isolation structure 150 (auxiliary electrode). The first electrode has a thinned portion, a thickness of which is less than a thickness of other regions of the first electrode. In one embodiment, an edge of the thinned portion is lapped with the isolation structure, and the thinned portion becomes thinner as it is closer to the isolation structure. This reduces a lap resistance while achieving an effective lap with the isolation structure, thereby avoiding potential display abnormalities.

In one implementation, one side of the first electrode is lapped with a side surface of part of the support portion 151 and the base portion 152, or is lapped with the base portion 152. In one implementation, edges on opposite sides of the first electrode each have the thinned portion, and the thinned portion is lapped with a side surface of part of the support portion 151 and the base portion 152, or is lapped with the base portion 152. The first electrode is a cathode, and the first electrode has the thinned portion and the body portion. The thinned portion is configured to have a thickness less than a thickness of other regions (e.g., the body portion). In one embodiment, the thinned portion may include a lap area and a transition area. The first electrode is obtained by full-surface evaporation during fabrication. In the isolation opening, the entire edge is the thinned portion, as long as at least part of the thinned portion is electrically connected to the isolation structure.

By taking a section of one sub-pixel as an example (the section being taken in a thickness direction of the substrate 130), further reference is made to FIG. 2 (where edges on the opposite sides of the first electrode are respectively lapped with the isolation structures) and FIG. 2a, where FIG. 2a is a schematic enlarged view of the left side of the dash-dotted line in FIG. 2 (where one side of the first electrode is lapped with the isolation structure). The first electrode has the thinned portion, a thickness of which in a thickness/film thickness direction (in a y direction) of the cathode is less than the thickness of other regions of the first electrode. In one embodiment, an edge of the thinned portion is lapped with the isolation structure, and the thinned portion becomes thinner as it is closer to the isolation structure. This reduces a lap resistance while achieving an effective lap of the cathode with the isolation structure, thereby avoiding potential display abnormalities. The thinned portion may be obtained by evaporation using a single evaporation source (also referred to as a single source) during preparation. In this implementation, a total height h3 (referring to FIG. 2) of the isolation structure is between 7000 and 15000 angstroms. In this implementation, as shown, one side of the cathode is lapped with the isolation structure, and a structure on the other opposing side of the cathode that is lapped with the isolation structure is the same or substantially the same (it is not possible to fabricate a completely symmetrical structure due to process limitations). In an x direction, a width of the roof portion 153 is wider than a width of the base portion 152. That is, a projection of the roof portion 153 on the pixel defining layer covers a projection of the base portion 152 on the pixel defining layer. An orthographic projection a of one end 153a of the roof portion 153 on the first electrode is in the transition area.

The pixel defining layer 140 is provided with a pixel opening, and an orthographic projection of the body portion on the substrate covers an orthographic projection of the pixel opening and part of the pixel defining layer 140 surrounding the pixel opening on the substrate. The pixel opening has an inclined surface 142. An included angle between the inclined surface 142 and a plane in which the substrate 130 is located/a plane in which the second electrode 141 is located is a (sometimes also referred to as a slope angle), where a is between 30° and 75° (30°, 45°, 60°, or 75°). One side of the inclined surface 142 covers the second electrode 141 (covering part of a surface of the second electrode), and the other side of the inclined surface 142 has a flat portion 142a. The flat portion 142a has the isolation structure 150 disposed thereon. The second electrode is an anode, which may be made of an ITO material, and is used for an electrical connection to the light-emitting unit thereon. In this implementation, a combination of inclined surfaces 142 encloses the pixel opening, and the pixel opening is in communication with the isolation opening. In this implementation, some of the film layers in the light-emitting unit, such as a light-emitting layer, may be prepared using a non-evaporation method, such as inkjet printing. In one embodiment, the method may be selected according to materials of the film layers. For example, in a case where the film layers are made of a polymer material and are not suitable for evaporation, inkjet printing may be used for preparation. The first electrode, that is, the cathode, may be prepared using an evaporation method. In this implementation, during preparation of the cathode, an evaporation apparatus is used to form a conductive layer on the light-emitting unit by evaporation in a collaborative manner, and then the first electrode (cathode) is obtained by etching (removing the conductive layer in irrelevant regions). The evaporation apparatus includes a first evaporation chamber CTD1 and a second evaporation chamber CTD2.

The evaporation is limited by an evaporation angle of an evaporation source in the first evaporation chamber CTD1 and in the second evaporation chamber CTD2.

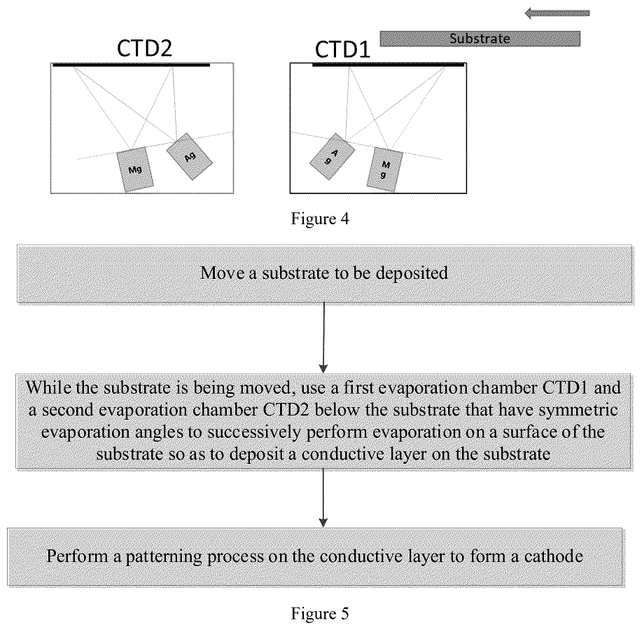

Next, referring to FIG. 3 and FIG. 4, an example in which the cathode covers the pixel defining layer (with the light-emitting unit below omitted) is used to describe the structure/morphology of the first electrode (cathode) formed by collaborative evaporation of the first evaporation chamber CTD1 and the second evaporation chamber CTD2. One side formed by evaporation of the second evaporation chamber CTD2 is lapped with the isolation structure/auxiliary cathode (referring to FIG. 4).

The first electrode 170 includes the thinned portion and the body portion. The thinned portion includes a lap area 171 and a transition area. The transition area includes a first transition area 172 and a second transition area 173.

The first transition area 172 is close to the lap area 171, and the second transition area 173 is close to the body portion. The lap area is lapped with the isolation structure, and (in the y direction) the lap area is lapped with the isolation structure, and the lap area becomes thinner as it is closer to the isolation structure. The lap area may be obtained by evaporation using a single evaporation source (also referred to as a single source) during preparation. A film thickness of the body portion is greater than a film thickness of the transition area, and the film thickness of the transition area is greater than a film thickness of the lap area. The body portion includes a body flat area 174 and a body ramp area 175. In this implementation, a film thickness of the body flat area is the same or substantially the same. A film thickness of the body ramp area 175 is the same as or substantially the same as the film thickness of the body flat area 174.

In one embodiment, a film thickness h2 of the first transition area 172 (i.e., a region of the first electrode/cathode corresponding to the orthographic projection of the end of the roof portion on the first electrode) is 70% or less of the film thickness h1 of the body flat area 174 of the body portion.

In one implementation, a ratio of the thickness h2 of the film layer (first transition area 172) corresponding to the orthographic projection of the end 153a of the roof portion 153 on the first electrode to the thickness h1 of the film layer of the body flat area 174 is less than or equal to 0.7 (i.e., 0.7 times or less). That is, the orthographic projection of the end on the first electrode is in the first transition area of the transition area, the body portion includes the body flat area, and the ratio of the thickness of the first transition area to the thickness of the film layer of the body flat area is less than or equal to 0.7. In one embodiment, the ratio of the thickness h2 of the first transition area 172 to the thickness h1 of the film layer of the body flat area 174 is between 0.3 and 0.7 (e.g., 0.3, 0.35, 0.4, 0.45, 0.5, 0.55, 0.6, 0.65, etc.). That is, the thickness h2 of the first transition area 172 corresponding to the orthographic projection of the end 153a of the roof portion 153 on the first electrode is 0.7 times or less of the thickness h1 of the body flat area 174.

In one embodiment, the film thickness h1 of the body flat area 174 is less than 2 times a thickness of the base portion 152 (in the y direction). Further, the film thickness h1 of the body flat area 174 is less than or equal to 1.5 times (e.g., 0.5, 0.6, 0.7, 0.8, 0.9, 1.0, 1.1, 1.2, 1.3, 1.4, or 1.5) the thickness of the base portion 152 (in the y direction). For example, the film thickness h1 of the body flat area 174 is 1.01 to 1.4 times the thickness of the base portion 152. For example, the film thickness h1 of the body flat area 174 is 0.5 to 1.4 times the thickness of the base portion 152.

In one implementation, the lap area 171 and the first transition area 172 of the first electrode/cathode are formed by evaporation of the second evaporation chamber CTD2 (referring to a region B in FIG. 3, i.e., single-source thinning). The second transition area 173, the body flat area 174 and the body ramp area 175 are formed by evaporation of both the first evaporation chamber CTD1 and the second evaporation chamber CTD2 (referring to a region A in FIG. 3). The body ramp area 175 covers a region corresponding to the inclined surface 142, to control the morphology of the prepared cathode and prepare the cathode with a predetermined shape (thickness). This implementation uses the collaborative evaporation of the first evaporation chamber CTD1 and the second evaporation chamber CTD2 to obtain the first electrode, and a region on a lap side of the first electrode and the isolation structure is formed by single-source evaporation of the first evaporation chamber CTD1 or the second evaporation chamber CTD2 to reduce the thickness of the first electrode. This can control the morphology of the prepared/deposited electrode to have a predetermined shape (thickness), and reduces a lap resistance while achieving an effective lap of the first electrode with the isolation structure, thereby avoiding potential display abnormalities.

It should be noted that the display panel may be further configured to include other functional structures. For example, the display panel may further include a touch structure to provide a touch function. For example, the touch structure may be a touch panel or a touch layer. The touch panel may be laminated into the display panel. For example, the touch layer may be directly prepared on an encapsulation layer of the display panel, which is conducive to a slim and lightweight design of the display panel.

FIG. 4 is a schematic diagram of an electrode (cathode) preparation system according to the present disclosure.

The preparation system includes an evaporation apparatus, which has two evaporation chambers, namely, a first evaporation chamber CTD1 and a second evaporation chamber CTD2. In one embodiment, an evaporation angle of the first evaporation chamber CTD1 is symmetric with an evaporation angle of the second evaporation chamber CTD2.

An evaporation source is configured in the first evaporation chamber CTD1 and in the second evaporation chamber CTD2. The evaporation source is a Mg-containing evaporation source, an Ag-containing evaporation source, or a combination thereof. In this implementation, the first evaporation chamber CTD1 has a first evaporation source and a second evaporation source, and the second evaporation chamber CTD2 has a third evaporation source and a fourth evaporation source. A material of the first evaporation source is the same as a material of the third evaporation source, such as a Mg-containing evaporation source. A material of the second evaporation source is the same as a material of the fourth evaporation source, such as an Ag-containing evaporation source. An evaporation angle of the Ag-containing evaporation source in the first evaporation chamber CTD1 is between 0 and 70°, and an evaporation angle of the Ag-containing evaporation source in the second evaporation chamber CTD2 is between 0 and −70°. An evaporation angle of 0° refers to a direction in which the evaporation source is perpendicular to the substrate. An evaporation angle is positive in the clockwise direction, and an evaporation angle is negative in the counterclockwise direction. A ratio of an evaporation rate of Mg to that of Ag in the same evaporation chamber is between 1:7 and 1:10. In one embodiment, the ratio of the evaporation rate of Mg to that of Ag is 1:9. A ratio of an evaporation rate of the second evaporation chamber CTD2 to that of the first evaporation chamber CTD1 is 1:1 to 2:1.

During preparation of the cathode, a substrate to be deposited is suspended above the first evaporation chamber CTD1 and the second evaporation chamber CTD2, and is moved from the first evaporation chamber CTD1 to the second evaporation chamber CTD2, to deposit a conductive layer on the substrate (which is patterned to obtain the cathode). For example, a carrier is used to suspend the substrate above the first evaporation chamber CTD1 and the second evaporation chamber CTD2. At this time, the substrate, the first evaporation chamber CTD1, and the second evaporation chamber CTD2 are all in a sealed environment.

FIG. 5 is a schematic flowchart of an electrode preparation method according to the present disclosure.

The preparation method utilizes the above-described preparation system and includes the following steps.

A substrate to be deposited is moved. This step utilizes a carrier to move the substrate to be deposited. In one embodiment, the substrate is moved from a first evaporation chamber CTD1 to a second evaporation chamber CTD2. In other implementations, the substrate may also be moved from the second evaporation chamber CTD2 to the first evaporation chamber CTD1.

While the substrate is being moved, the first evaporation chamber CTD1 and the second evaporation chamber CTD2 below the substrate that have symmetric evaporation angles are used to successively perform evaporation on a surface of the substrate to deposit a conductive layer on the substrate.

A patterning process is performed on the conductive layer to form a cathode.

A ratio of an evaporation rate of the second evaporation chamber CTD2 to that of the first evaporation chamber CTD1 is between 1:1 and 2:1, an evaporation angle of an Ag-containing evaporation source in the first evaporation chamber CTD1 is between 0 and 70° (0° is a direction perpendicular to the substrate), and an evaporation angle of an Ag-containing evaporation source in the second evaporation chamber CTD1 is between 0 and −70°. With the preparation method, the symmetric or approximately symmetric first evaporation chamber CTD1 and second evaporation chamber CTD2 are used to adjust the morphology of a cathode film formation to obtain a cathode with a specific morphology (to reduce a thickness of a lap area), to reduce a lap resistance while achieving an effective lap of the cathode with the isolation structure/auxiliary electrode, thereby reducing lap-related abnormalities. An evaporation angle of 0° refers to a direction in which the evaporation source is perpendicular to the substrate. An evaporation angle is positive in the clockwise direction, and an evaporation angle is negative in the counterclockwise direction.

In one embodiment, the cathode preparation method is used in an LED display panel to prepare a cathode. Further, the conductive layer deposited by the preparation method is stacked on a light-emitting functional layer in such a way that a cathode of a light-emitting device/sub-pixel with a specific morphology is obtained, which reduces a lap resistance while achieving a reliable lap, thereby reducing subsequent display abnormalities.

Some other embodiments of the present application provide a display apparatus, including a display panel in the above-described embodiments. The display apparatus has a pixel density in a range of 400 PPI to 7000 PPI that is suitable for scenarios such as TVs and laptop computers, and can also make the product suitable for usage scenarios of micro-display products (e.g., AR, VR, etc.). Further, the display apparatus may be a television, a digital camera, a mobile phone, a watch, a tablet computer, a laptop computer, a navigator, a console, or any other product or component having a display function.

It should be noted that some embodiments of the present disclosure are described above. Other embodiments are within the scope of the appended claims. In some cases, the actions or steps recited in the claims can be performed in an order different from that in the above embodiments, and can still achieve desired results. In addition, the processes depicted in the accompanying drawings are not necessarily required to be shown in a particular or sequential order, to achieve desired results. In some implementations, multi-task processing and parallel processing are also possible or may be advantageous.

The embodiments of the present disclosure are intended to cover all such substitutions, modifications, and variations that fall within the broad scope of the appended claims. Therefore, any omissions, modifications, equivalent substitutions, improvements etc., made within the spirit and principle of the embodiments of the present disclosure are intended to be included within the scope of protection of the present disclosure.

1. A display panel, comprising:
a substrate, light-emitting units, first electrodes, and an isolation structure, wherein
the isolation structure is disposed on one side of the substrate and encloses a plurality of isolation openings,
at least part of the light-emitting unit is located within the isolation opening, and
the first electrode covers the light-emitting unit and comprises a thinned portion and a body portion, the body portion covering a central region of the isolation opening and extending outwardly to form the thinned portion, at least part of the thinned portion being electrically connected to the isolation structure, and a thickness of the thinned portion being less than a thickness of the body portion.

2. The display panel according to claim 1, wherein an edge of the thinned portion is lapped with the isolation structure, and the thinned portion becomes thinner as it is closer to the isolation structure.

3. The display panel according to claim 2, wherein the thinned portion comprises a lap area and a transition area, the lap area being electrically connected to the isolation structure.

4. The display panel according to claim 1, wherein edges on opposite sides of the first electrode are electrically connected to the isolation structure.

5. The display panel according to claim 4, wherein the thinned portion of each of the edges on the opposite sides of the first electrode comprises a lap area and a transition area, the lap area being electrically connected to the isolation structure.

6. The display panel according to claim 4, wherein the transition area is located between the body portion and the lap area and comprises a first transition area and a second transition area, the first transition area being close to the lap area, the second transition area being close to the body portion, and the lap area being electrically connected to the isolation structure.

7. The display panel according to claim 1, wherein the isolation structure comprises support portions, base portions, and roof portions, one side of the support portion being disposed on the base portion, the base portion being disposed on the substrate, the roof portion being disposed on one side of the support portion away from the substrate, the roof portion having an end on either side, and a thickness of a region corresponding to an orthographic projection of the end on the first electrode is less than or equal to 70% of the thickness of the body portion of the first electrode.

8. The display panel according to claim 7, wherein the orthographic projection of the end on the first electrode is in the transition area, and a ratio of a thickness of the transition area to the thickness of the body portion is less than or equal to 0.7.

9. The display panel according to claim 7, wherein the ratio of the thickness of the transition area to the thickness of the body portion is in a range of 0.3 to 0.7.

10. The display panel according to claim 7, wherein the orthographic projection of the end on the first electrode is in a first transition area of the transition area, and a ratio of a thickness of the first transition area to the thickness of the body portion is less than or equal to 0.7.

11. The display panel according to claim 7, wherein a thickness ratio of the body portion to the base portion is less than 2.

12. The display panel according to claim 11, wherein the thickness ratio of the body portion to the base portion is less than or equal to 1.5.

13. The display panel according to claim 7, wherein the first electrode is lapped with a side surface of part of the support portion and the base portion, or is lapped with the base portion.

14. The display panel according to claim 13, wherein the thinned portion is lapped with the side surface of part of the support portion and the base portion, or is lapped with the base portion.

15. The display panel according to claim 1, further comprising:
a pixel defining layer disposed on the substrate, wherein the isolation structure is disposed on one side of the pixel defining layer away from the substrate.

16. The display panel according to claim 15, further comprising:
a planarization layer disposed on one side of the substrate, wherein the pixel defining layer is disposed on one side of the planarization layer away from the substrate, and the one side of the planarization layer away from the substrate has a second electrode disposed thereon.

17. The display panel according to claim 16, wherein the planarization layer covers an active area or covers the active area and a non-active area outside the active area.

18. The display panel according to claim 15, wherein the pixel defining layer is provided with a plurality of pixel openings, an orthographic projection of the body portion on the substrate covers an orthographic projection of the pixel opening and part of the pixel defining layer surrounding the pixel opening on the substrate, and the pixel opening corresponds in position to the isolation opening and has an inclined surface.

19. The display panel according to claim 18, wherein an included angle α between the inclined surface and a plane in which the substrate is located is between 30° and 75°.

20. A display module, comprising:
a display panel, comprising:
a substrate, light-emitting units, first electrodes, and an isolation structure, wherein
the isolation structure is disposed on one side of the substrate and encloses a plurality of isolation openings,
at least part of the light-emitting unit is located within the isolation opening, and
the first electrode covers the light-emitting unit and comprises a thinned portion and a body portion, the body portion covering a central region of the isolation opening and extending outwardly to form the thinned portion, at least part of the thinned portion being electrically connected to the isolation structure, and a thickness of the thinned portion being less than a thickness of the body portion.
